(19) United States
(12) Patent Application Publication
(10) Pub. No.: US 2011/0088782 A1
(43) Pub. Date: Apr. 21, 2011

(54) PHOTOELECTRIC CONVERSION SEMICONDUCTOR LAYER, METHOD FOR PRODUCING THE SAME, PHOTOELECTRIC CONVERSION DEVICE AND SOLAR BATTERY

(75) Inventor: Masashi SHIRATA, Ashigarakami-gun (JP)

(73) Assignee: FUJIFILM CORPORATION, Tokyo (JP)

(21) Appl. No.: 12/907,425

(22) Filed: Oct. 19, 2010

(30) Foreign Application Priority Data
Oct. 21, 2009 (JP) 2009-242076

(51) Int. Cl. H01L 31/0264; H01L 31/0352

(52) U.S. Cl. 136/262; 136/264; 136/265

(57) ABSTRACT

A photoelectric conversion device includes a photoelectric conversion semiconductor layer for generating an electric current when it absorbs light, a first electrode formed in contact with a light-absorbing surface of the semiconductor layer, and a second electrode formed in contact with a rear surface of the semiconductor layer. The semiconductor layer is a single-particle film including a binder layer and separate photoelectric conversion semiconductor particles. At least parts of the photoelectric conversion semiconductor particles are embedded in the binder layer. The photoelectric conversion semiconductor particles have a mean particle diameter of not less than 1 μm and not more than 60 μm and a variation coefficient of particle diameter of less than 30%. Parts of the semiconductor particles are in contact with the second electrode at the rear surface and parts of the semiconductor particles are in contact with the first electrode at the front surface via a buffer layer.

### BACKGROUND OF THE INVENTION

1. Field of the Invention

The present invention relates to a photoelectric conversion semiconductor layer and a method for producing the photoelectric conversion layer, as well as a photoelectric conversion device using the photoelectric conversion semiconductor layer and a solar battery.

2. Description of the Related Art

Photoelectric conversion devices having a multilayer structure, which includes a lower electrode (back electrode), a photoelectric conversion semiconductor layer which generates an electric current when it absorbs light, and an upper electrode, are used in applications such as solar batteries.

The main stream of conventional solar batteries has been Si solar batteries, which use bulk single-crystal Si or polycrystal Si, or thin-film amorphous Si. On the other hand, compound semiconductor solar batteries, which do not depend on Si, are now being researched and developed. As the compound semiconductor solar batteries, those of a bulk type, such as GaAs solar batteries, etc. and those of a thin-film type, such as CIS (Cu—In—Se) or CIGS (Cu—In—Ga—Se) solar batteries, which contain a group Ib element, a group IIIb element and a group VIb element, are known. The CIS or CIGS solar batteries are reported to have a high light absorption rate and high energy conversion efficiency.

As a method for producing a CIGS layer, a three-step process, a selenization process, etc., have been known. However, these processes are vacuum film formation processes and require high costs and large investment.

As a method using a non-vacuum process for producing the CIGS layer at low costs, a method of forming a film by coating particles containing Cu, In, Ga and Se has been proposed. Further, a method involving coating spherical CIGS particles on a substrate and firing the CIGS particles at a high temperature around 500° C. to crystallize the particles has been proposed in S. Ahn et al., “Nanoparticle derived Cu(In,Ga)Se₂ absorber layer for thin film solar cells”, Colloids and Surfaces A: Physicochemical and Engineering Aspects, Vols. 313-314, 2008, pp. 171-174 (hereinafter, Non-Patent Document 1) and S. Ahn et al., “Effects of heat treatments on the properties of Cu(In,Ga)Se₂ nanoparticles”, Solar Energy Materials and Solar Cells, Vol. 91, Issue 19, 2007, pp. 1836-1841 (hereinafter, Non-Patent Document 2). In these documents, reduction of heating time in a rapid thermal process (RTP) is studied.

A method involving coating one or more types of spherical oxide particles or alloy particles containing Cu, In and Ga on a substrate, and applying a heat treatment at a high temperature around 500° C. under the presence of Se gas to achieve selenization and crystallization has been proposed in U.S. Patent Application Publication No. 20050183768 (hereinafter, Patent Document 1), M. Kaelin et al., “CIS and CIGS layers from selenized nanoparticle precursors”, Thin Solid Films, Vols. 431-432, 2003, pp. 58-62 (hereinafter, Non-Patent Document 3) and Non-Patent Document 2.

All of the above-mentioned processes essentially require a heat treatment at a high temperature around 500° C. Equipment for a high-temperature process is expensive and imposes a great burden of costs. Further, assuming a continuous process using a ribbon-like continuous flexible substrate (a Roll to Roll process), the heat treatment requires at least about five minutes even when the RTP disclosed in Non-Patent Documents 1 and 2 is used. With a typical conveyance speed in a Roll to Roll process for producing a semiconductor device, the heat treatment time of about five minutes is very long and requires an impractical length of the firing furnace. Therefore, it is preferred to form the CIGS layer at a temperature as low as possible.

A CIGS layer formed by a single particle layer of CIGS particles has been proposed in each of M. Altosaar et al., “Monograin layer solor cells”, Thin Solid Films, Vols. 431-432, 2003, pp. 466-469 (hereinafter, Non-Patent Document 4), M. Altosaar et al., “Further developments in CIS monograin layer solar cells technology”, Solar Energy Materials & Solar Cells, Vol. 87, 2005, pp. 25-32 (hereinafter, Non-Patent Document 5), M. Kauk et al., “The performance of CuInSe₂ monograin layer solar cells with variable indium content”, Thin Solid Films, Vol. 515, 2007, pp. 5880-5883 (hereinafter, Non-Patent Document 6), M. Altosaar and E. Mellikov, “CuInSe₂ Monograin Growth in CuSe—Se Liquid Phase”, Jpn. J. Appl. Phys. Vol. 39, 2000, Suppl. 39-1, pp. 65-66 (hereinafter, Non-Patent Document 7) and in U.S. Pat. No. 6,488,770 and U.S. Patent Application Publication No. 20070189956 (hereinafter, Patent Documents 2 and 3, respectively). These CIGS layers do not require a high temperature heat treatment after the coating film formation. Theses documents are written by the same researchers.

The CIGS layers disclosed in Non-Patent Documents 4 to 7 and Patent Documents 2 and 3 are single particle layers. Therefore, if there is a large variation in the particle diameter of the particles, the interelectrode distance varies and it is difficult to provide a predetermined voltage in a stable manner. Therefore, it is preferred to provide a small variation in the particle diameter of the particles forming the CIGS layer, which is a single particle layer. Although Patent Document 2 states in paragraph 0018 that a difference in the particle size of the CIGS powder in a batch is slight, no data supporting that statement and no method for controlling the particle size are disclosed in Patent Document 2. In fact, the present inventors tested the content of Patent Document 2 and the resulting variation coefficient of the particle diameter was 50% or more, which is a large variation.

In the techniques disclosed in these documents, in order to reduce influence of the variation of particle diameter, a soft carbon electrode is mainly used as an electrode provided on a side where no light absorption is performed. However, even the influence of the variation of particle diameter is reduced, the carbon electrode has a large resistance, and this degrades the photoelectric conversion efficiency. A conversion efficiency of 9.5%, which is calculated for an area excluding non-light receiving areas, such as the electrode, is reported in Non-Patent Document 6. This value is equivalent to 5.7% when converted into a common conversion efficiency rate. This value is less than half of typical photoelectric conversion efficiency of a CIGS layer formed through a vacuum film formation process, and is not a practical level.

### SUMMARY OF THE INVENTION

In view of the above-described circumstances, the present invention is directed to providing a photoelectric conversion semiconductor device having good output stability and photoelectric conversion efficiency, which can be produced without requiring a high temperature process over 250° C. and thus at lower costs than those produced using a vacuum film formation process, as well as a solar battery provided with the photoelectric conversion semiconductor device.

The invention is also directed to providing a photoelectric conversion semiconductor device with good durability and a solar battery provided with the photoelectric conversion semiconductor device.

An aspect of the photoelectric conversion device of the invention is a photoelectric conversion device including: a photoelectric conversion semiconductor layer for generating an electric current when it absorbs light; a first electrode formed in contact with a front surface forming a light absorbing surface of the semiconductor layer; and a second electrode formed in contact with a rear surface of the semiconductor layer, wherein the semiconductor layer is a single particle film including a binder layer and separate photoelectric conversion semiconductor particles, at least parts of the photoelectric conversion semiconductor particles being embedded in the binder layer, the photoelectric conversion semiconductor particles having a mean particle diameter of not less than 1 μm and not more than 60 μm and a variation coefficient of particle diameter of less than 30%, and wherein parts of the semiconductor particles are in contact with the second electrode at the rear surface and parts of the semiconductor particles are in contact with the first electrode at the front surface via a buffer layer.

The “mean particle diameter” herein refers to a median diameter. Values of the “mean particle diameter” and the “variation coefficient of particle diameter” may be measured, for example, using a laser scattering method, such as using a laser diffraction/scattering particle size distribution measurement apparatus LA-920 available from HORIBA, Ltd.

The description “separate photoelectric conversion semiconductor particles” herein refers to single semiconductor particles which are independent from each other. The “single particle film” refers to a film formed by the single particles arranged in an in-plane direction of the film with one particle in the film thickness direction. However, there may be such cases that that some of the semiconductor particles are broken during the film formation process and thus two or more particles are present in the film thickness direction, i.e., relatively flat particles pile on top of the other. Such particles may be present at a maximum of about 10% of the number of all the particles in the in-plane direction of the film.

The description “parts of the semiconductor particles” refers both to a part of each semiconductor particle and some particles of the semiconductor particles.

In the photoelectric conversion device of the invention, the second electrode may be a metal electrode.

Further, the main component of the separate photoelectric conversion semiconductor particles may be at least one compound semiconductor having a chalcopyrite structure, and may optionally be at least one compound semiconductor containing a group Ib element, a group IIIb element and a group VIb element. The “main component” is defined herein as a component that is contained at a content of at least 80 mol %.

The compound semiconductor may be at least one compound semiconductor containing at least one group Ib element selected from the group consisting of Cu and Ag, at least one group IIIb element selected from the group consisting of Al, Ga and In, and at least one group VIb element selected from the group consisting of S, Se and Te.

The solar battery of the invention includes the above-described photoelectric conversion device of the invention.

The present inventors have found that smoothness at the interface between the photoelectric conversion semiconductor layer and each electrode largely influences the durability as well as the photoelectric conversion efficiency of the photoelectric conversion device when it is used as a solar battery. Moreover, the present inventors have found that, with respect to a photoelectric conversion semiconductor device employing a photoelectric conversion semiconductor layer made of a single particle film, properties of the photoelectric conversion semiconductor devices are dramatically improved by providing the variation coefficient of particle diameter of less than 30%.

Japanese Unexamined Patent Publication No. 2001-085076 discloses a photoelectric conversion device including semiconductor particles which are obtained from a metal hydroxide gel or a precursor thereof present in a hydrophilic solvent. This patent document teaches metal chalcogenide as the semiconductor particles, and that the variation coefficient of the particle size distribution is preferably less than 30%.

However, the technique disclosed in this patent document is directed to increasing the specific surface area and improving the homogeneity of a photoelectric conversion layer which is mainly composed of a porous titanium dioxide thin film, in order to increase the short-circuit current, thereby increasing the photoelectric conversion efficiency. This document does not teach or suggest the association between the variation coefficient and the durability. Further, with respect to chalcogenides other than oxides, although some methods thereof are mentioned, for example, in paragraph [0021], no data that was actually achieved with the variation coefficient of less than 30% is disclosed. As is stated in the specification of this patent document, the oxide semiconductor particles can be provided from the metal hydroxide gel or the precursor thereof only through a reaction by hydrolysis at a relatively low temperature. However, with respect to chalcogenides other than oxides, it is impossible to produce semiconductor particles through hydrolysis at a low temperature, and high temperature annealing in a chalcogen atmosphere is required. In such a process, it is difficult to control the variation coefficient since annealing is accompanied by particle growth.

The present inventors have first found a device design that achieves a highly durable photoelectric conversion device including a photoelectric conversion semiconductor layer made of a single particle film, and have achieved both high output stability and high durability, as a result. The present invention is not easily conceivable even with the teachings in Patent Documents 2 and 3 and Japanese Unexamined Patent Publication No. 2001-085076.

The photoelectric conversion device of the invention includes a single particle film, in which at least parts of separate photoelectric conversion semiconductor particles, which have a mean particle diameter of not less than 1 μm and not more than 60 μm and a variation coefficient of particle diameter of less than 30%, are embedded. With this structure provided with a small variation coefficient of particle diameter of the semiconductor particles, a single particle film photoelectric conversion device with low variation of the interelectrode distance can be achieved.

Therefore, according to the invention, a photoelectric conversion semiconductor device with good output stability and good photoelectric conversion efficiency, and a solar battery provided with the photoelectric conversion semiconductor device can be provided without requiring a high temperature process over 250° C. and thus at lower costs than those produced using a vacuum film formation process.

### BRIEF DESCRIPTION OF THE DRAWINGS

FIG. 1 is a sectional view illustrating one embodiment of a photoelectric conversion device of the present invention,

FIG. 2 shows a relationship between lattice constant and bandgap of compound semiconductors, and

FIG. 3 is a sectional view illustrating flow of a method for producing the photoelectric conversion device of the invention.

### DESCRIPTION OF THE PREFERRED EMBODIMENTS

### Photoelectric Conversion Semiconductor Device

### Solar Battery

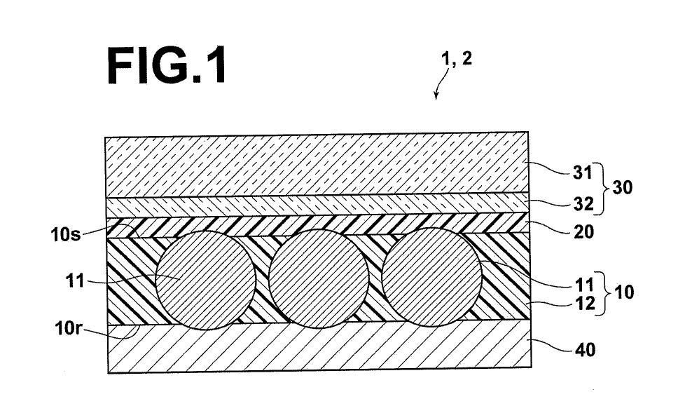

Now, one embodiment of a photoelectric conversion device according to the present invention will be described with reference to the drawings. FIG. 1 is a schematic sectional view taken along the thickness direction illustrating the structure of a photoelectric conversion device of this embodiment. For ease of visual recognition, the elements shown in the drawings are not to scale.

As shown in the drawing, the photoelectric conversion device 1 includes: a photoelectric conversion semiconductor layer 10, which generates an electric current when it absorbs light; a first electrode 30 formed in contact with a surface 10s forming a light absorbing surface of the photoelectric conversion semiconductor layer 10; and a second electrode 40 formed in contact with a rear surface 10r of the photoelectric conversion semiconductor layer 10. The photoelectric conversion semiconductor layer 10 is a single particle film, in which at least parts of individual separate photoelectric conversion semiconductor particles 11 are embedded in a binder layer 12.

The semiconductor particles 11 have a mean particle diameter of not less than 1 μm and not more than 60 μm, and a variation coefficient of particle diameter of less than 300. At the rear surface 10r, parts of the semiconductor particles 11 are in contact with the second electrode 40. At the surface 10s, parts of the semiconductor particles 11 are in contact with the first electrode 30 via a buffer layer 20.

The first electrode 30 and the second electrode 40 are made of a conductive material. The first electrode 30 provided at the light incident side needs to be translucent.

The main component of the second electrode 40 is not particularly limited; however, it may be a metal in view of good conductivity. Examples of the metal may include Mo, Cr, W and a combination thereof, and in particular, Mo. The thickness of the second electrode 40 is not particularly limited; however, it may be in the range from 0.3 to 1.0 μm.

The main component of the first electrode 30 is not particularly limited, and examples thereof may include ZnO, ITO (indium tin oxide), SnO₂ or a combination thereof. These materials are highly translucent and have low resistance. The first electrode 30 contains any of such materials and a dopant to provide a desired conductivity type. Examples of the dopant may include Ga, Al, B, etc.

The thickness of the first electrode 30 is not particularly limited; however, it may be in the range from 0.6 to 1.0 μm.

The first electrode 30 and/or the second electrode 40 may have a single-layer structure or a multilayer structure, such as a double-layer structure. The first electrode 30 may have a double-layer structure including, in the order from the buffer layer 20 side, an i-layer 32 having i-type conductivity and an n-layer 31 having n-type conductivity (the conductivity type may be p-type depending on the entire layer structure).

The film formation method used to form the second electrode 40 and the first electrode 30 is not particularly limited, and examples thereof include vapor-phase film formation processes, such as electron beam vapor deposition and sputtering.

The main component of the buffer layer 20 is not particularly limited, and examples thereof may include CdS, ZnS, ZnO, ZnMgO, ZnS (O, OH) and a combination thereof. The buffer layer 20 containing any of these compounds can form a junction interface where no rebinding between the photoelectric conversion layer and a carrier occurs, as is disclosed, for example, in Japanese Unexamined Patent Publication No. 2002-343987.

The thickness of the buffer layer 20 is not particularly limited; however, it may be in the range from 0.03 to 0.1 μm. In this embodiment, the buffer layer 20 covers the photoelectric conversion layer 10. However, the buffer layer 20 may be formed to cover the surface of the second electrode 40 other than areas thereof contacting the separate photoelectric conversion semiconductor particles 11 in the photoelectric conversion layer 10.

An example combination of the layer structure may, for example, be as follows: Mo electrode/CdS buffer layer/CIGS photoelectric conversion layer/ZnO electrode.

The conductivity types of the photoelectric conversion semiconductor layer 10, the buffer layer 20, the first electrode 30 and the second electrode 40 are not particularly limited. Usually, the photoelectric conversion semiconductor layer 10 is p-type, the buffer layer 40 is n-type (such as n-CdS), and the first electrode 30 is n-type (such as an n-ZnO layer) or has a multilayer structure, as described above, which includes an i-type layer and an n-type layer (such as an i-ZnO layer and an n-ZnO layer). With these conductivity types, a p-n junction or a p-i-n junction is formed between the photoelectric conversion semiconductor layer 10 and the first electrode 30.

As has been described previously, the photoelectric conversion semiconductor layer 10 is a single particle film, in which at least parts of the individual separate photoelectric conversion semiconductor particles 11 (hereinafter, “semiconductor particles 11”) are embedded in the binder layer 12. At the rear surface 10r, parts of the semiconductor particles 11 are in contact with the second electrode 40. At the surface 10s, parts of the semiconductor particles 11 are in contact with the first electrode 30 via a buffer layer 20.

The binder layer 12 is not particularly limited; however, it may be an organic binder, such as polyethylene, polypropylene, polyester or polystyrene. The thickness of the binder layer 12 is not particularly limited as long as sufficient contact between the semiconductor particles 11 and the buffer layer 20 and between the semiconductor particles 11 and the second electrode 40 is provided and the particles are immobilized in a stable manner.

The semiconductor particles 11 of this embodiment are not particularly limited; however, the main component thereof may be at least one compound semiconductor having a chalcopyrite structure.

The compound semiconductor having a chalcopyrite structure may be at least one compound semiconductor containing a group Ib element, a group IIIb element and a group VIb element. In view of high light absorptance and high photoelectric conversion efficiency, the main component of the semiconductor particles 11 may be at least one compound semiconductor (S) which contains:

at least one group Ib element selected from the group consisting of Cu and Ag;

at least one group IIIb element selected from the group consisting of Al, Ga and In; and

at least one group VIb element selected from the group consisting of S, Se and Te.

Description of element groups herein is based on the short-period form of the periodic table. The compound semiconductor containing a group Ib element, a group IIIb element and a group VIb element may herein be referred to as a “group semiconductor”. The group semiconductor may contain one or two or more group Ib elements, group IIIb elements and group VIb elements, respectively.

Examples of the compound semiconductor (S) may include

CuAlS₂, CuGaS₂, CuInS₂,

CuAlSe₂, CuGaSe₂, CuInSe₂ (CIS)

AgAlS₂, AgGaS₂, AgInS₂,

AgAlSe₂, AgGaSe₂, AgInSe₂,

AgAlTe₂, AgGaTe₂, AgInTe₂,

Cu (In₁₋ₓGaₓ) Se₂ (CIGS) Cu (In₁₋ₓAlₓ) Se₂, Cu (In₁₋ₓGaₓ) (S, Se)₂,

Ag (In₁₋ₓGaₓ) Se₂ and Ag (In₁₋ₓGaₓ) (S, Se)₂.

The semiconductor particles 11 may contain at least one of CuInS₂, CuInSe₂ (CIS), or Cu (In, Ga) S₂ or Cu (In, Ga) Se₂ (CIGS) which are obtained by adding Ga to CuInS₂ or CuInSe₂ to provide a solid solution, or a sulfide-selenide thereof. The CIS, CIGS, etc., are reported to have a high light absorption rate and high energy conversion efficiency. Further, they are less susceptible to degradation of efficiency due to exposure to light and have excellent durability.

If the semiconductor particles 11 are CIGS particles, the Ga concentration and the Cu concentration in the layer are not particularly limited. A molar ratio of the Ga content to the content of all the group III elements in the particles may be in the range from 0.05 to 0.6, or may optionally be in the range from 0.2 to 0.5.

A molar ratio of the Cu content to the content of all the group III elements in the particles may be in the range from 0.7 to 1.0, or may optionally be in the range from 0.8 to 0.98.

The semiconductor particles 11 contain an impurity to provide a desired semiconductor conductivity type. The impurity can be added to the semiconductor particles by diffusion from an adjacent layer and/or actively by doping.

The semiconductor particles 11 may contain, for example, one or two or more semiconductors other than the group semiconductor. Examples of the semiconductors other than the group semiconductor may include: a semiconductor containing a group IVb element (group IV semiconductor), such as Si; a semiconductor containing a group IIIb element and a group Vb element (group III-V semiconductor), such as GaAs; and a semiconductor containing a group IIb element and a group VIb element (group II-VI semiconductor), such as CdTe.

The semiconductor particles 11 may contain any component other than the semiconductor and the impurity to provide a desired conductivity type as long as the properties thereof are not impaired.

The semiconductor particles 11 may be formed by particles having the same composition, or two or more kinds of particles having different compositions.

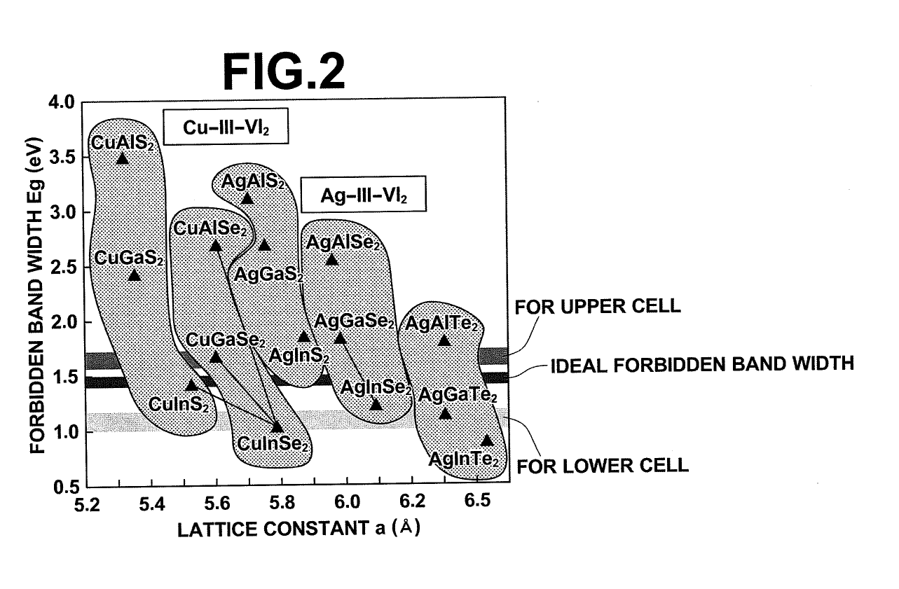

FIG. 2 shows a relationship between lattice constant and bandgap of typical I-III-VI compound semiconductors. It can be seen from FIG. 2 that various forbidden band widths (bandgaps) can be provided by varying the composition ratio. A desired forbidden band width can be provided by changing the composition of the group Ib element, the group IIIb element and the group VIb element in the semiconductor particles 11. In the above-described compound semiconductor (S), the element to have the concentration varied in the thickness direction may be at least one element selected from the group consisting of Cu, Ag, Al, Ga, In, S, Se and Te, and in particular, at least one element selected from the group consisting of Ag, Ga, Al and S. In the case of CIGS, for example, potential control in the range from 1.04 to 1.68 eV can be achieved by varying the concentration of Ga.

The semiconductor particles 11 of this embodiment have a mean particle diameter of not less than 1 μm and not more than 60 μm, and a variation coefficient of particle diameter of less than 30%. The photoelectric conversion semiconductor layer 10 is a single particle film, and therefore has a basic structure in which a single semiconductor particle 11 is present between the electrodes in the thickness direction, as shown in the drawings. Therefore, the lower limit of the mean particle diameter of the semiconductor particles 11 is a particle diameter that allows formation of a single particle film, and it is believed that a single particle film can be formed with the mean particle diameter of at least 1 μm. The upper limit is determined with consideration that an excessively large mean particle diameter results in an unnecessarily high series resistance in a photovoltaic application and is wasteful.

Further, since the photoelectric conversion semiconductor layer 10 is a single particle film, if there is large variation in the particle diameters of the individual semiconductor particles 11, the layer surface has poor smoothness, resulting in variation in the interelectrode distance of the photoelectric conversion device, which hinders providing a predetermined voltage and output in a stable manner. Therefore, a smaller variation coefficient of particle diameter of the semiconductor particles 11 is preferred. A smaller variation coefficient allows providing sufficient contact between the individual semiconductor particles 11 and the electrodes, thereby providing less rebinding between electrons and holes in the photoelectric conversion semiconductor layer 10 and smaller loss, such as heat generation, and thus is believed to provide higher photoelectric conversion efficiency.

Further, the present inventors have found that, with respect to a photoelectric conversion device including a photoelectric conversion semiconductor layer made of a single particle film, smoothness at the interface between the photoelectric conversion semiconductor layer and each electrode largely influences the durability as well as the photoelectric conversion efficiency of the photoelectric conversion device when it is used, for example, as a solar battery. Moreover, the present inventors have found that, with respect to a photoelectric conversion semiconductor device employing a photoelectric conversion semiconductor layer made of a single particle film, the photoelectric conversion efficiency and the durability of the photoelectric conversion semiconductor device are dramatically improved by providing the variation coefficient of particle diameter of less than 30% (see Table 1).

The present inventors believe that, with respect to a photoelectric conversion device including a photoelectric conversion semiconductor layer made of a single particle film, if semiconductor particles having a large variation coefficient are used, smaller size particles do not contact the upper and lower electrodes, and therefore, they not only fail to contribute to photoelectric conversion, but also are more likely to cause degradation of the photoelectric conversion efficiency due to volatilization of the constitute elements (such as chalcogen) than larger particles. Further, it is believed that, since it is difficult to maintain smoothness of the interface between each electrode and the photoelectric conversion semiconductor layer, further deterioration due to distortion of the electrode surfaces may be promoted. The present inventors infer that these influences have dramatically been reduced and the durability has dramatically been improved by providing the variation coefficient of particle diameter of less than 30%.

Therefore, with respect to the photoelectric conversion device 1, the variation coefficient of particle diameter of the semiconductor particles 11 is defined as less than 30%. As shown in Table 1 with respect to Examples described later, the photoelectric conversion devices 1 provided in the Examples had high electricity generation efficiency exceeding 9.0% and good durability with low degradation of photoelectric conversion efficiency after 1000 hours.

Now, a method for producing the photoelectric conversion device 1 is described.

First, the separate photoelectric conversion semiconductor particles 11 (semiconductor particles 11) are produced. The method for producing the semiconductor particles 11 is not particularly limited as long as the semiconductor particles 11 having a mean particle diameter in the range from 1 to 60 μm and a variation coefficient of less than 30% are provided. Such semiconductor particles 11 can be provided using any of known particle synthesis methods and sieving the resulting particles to provide the variation coefficient of less than 30%. However, in order to minimize production loss, it is preferred to use a method which allows control of the particle diameter as easy as possible to produce the semiconductor particles, and then sieve the produced particles. For example, a method for producing a powder disclosed in Patent Document 2 may be used.

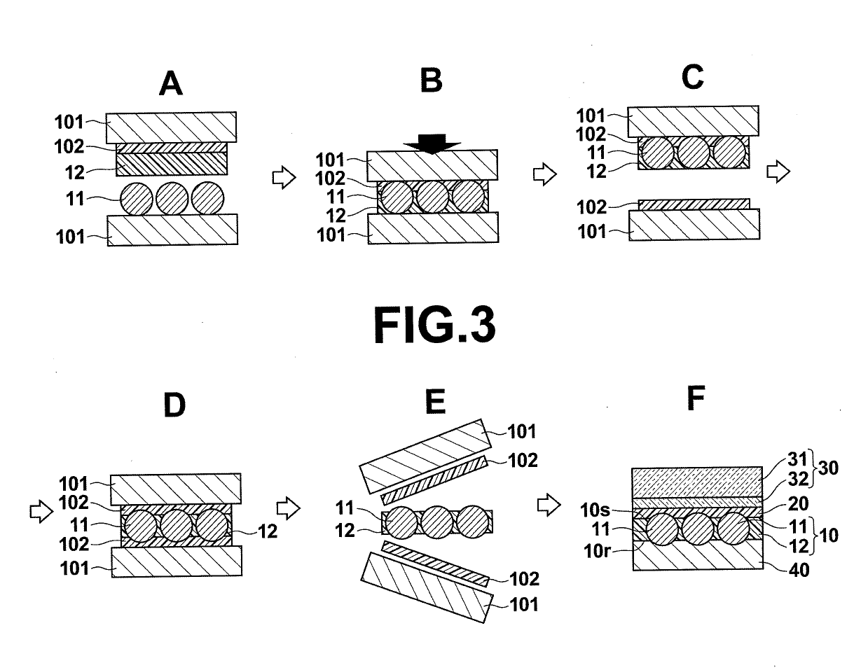

Then, the photoelectric conversion device 1 is produced using the thus produced semiconductor particles 11. FIG. 3 illustrates flow of a process for producing the photoelectric conversion device 1.

As shown at “A” in FIG. 3, a pair of metal plates 101 are prepared, and the semiconductor particles 11 are disposed over one of the metal plates 101 to form a single particle layer. The formation of the single particle layer may be achieved by providing a weak adhesion layer or by providing regular depressions under the semiconductor particles 11 to immobilize the semiconductor particles 11. The other of the metal plates 101 holds a Gel-Pak sheet 102 (GEL-FILM (trademark) WF-40/1.5-X4 available from Gel-Pak Inc.), which includes an adhesive polymer layer in the form of an elastic gel, and a polypropylene film 12, which has an appropriate thickness (the range of the thickness is as described above), in this order. Although the polypropylene film is used in this example, the polymer film forms the binder layer 12, as indicated by the reference numeral, and therefore the type of the film may be selected according to the material of the binder layer 12.

Then, as shown at “B”, the polypropylene film 12 is positioned to cover the semiconductor particles 11, and a pressure is applied from the rear side of the metal plates 101. In the pressurized state, heating at a temperature not less than the melting temperature of the polypropylene film is carried out, and then cooling is carried out after the polypropylene film has sufficiently melted. The pressure here is an enough pressure to make the Gel-Pak sheet 102 sufficiently contact the head portions of the semiconductor particles 11 without applying excessive stress to the semiconductor particles 11. For example, in a state where a pressure of 180 g/cm² is applied, heating may be carried out at a temperature of 200° C. for a few minutes, and cooling may be achieved in ambient air.

Then, as shown at “C” and “D” in FIG. 3, the same operation is carried out on the opposite side of the semiconductor particles 11, and then, the metal plates 101 and the Gel-Pak sheets 102 are peeled off to provide the photoelectric conversion semiconductor layer 10 with the head portions and the bottom portions of the semiconductor particles 11 being exposed (“E” in FIG. 3). According to this method, a sufficient number of separate photoelectric conversion semiconductor particles 11 can easily be exposed at the contact surfaces to contact the electrodes.

Finally, the second electrode 40 is formed on the rear surface 10r of the thus obtained photoelectric conversion semiconductor layer 10, and the buffer layer 20 and the first electrode layer 40 are sequentially formed on the surface 10s to provide the photoelectric conversion device 1.

The photoelectric conversion device 1 is preferably applicable to a solar battery 2. The solar battery can be formed by attaching a cover glass, a protective film, etc., to the photoelectric conversion device 1, as necessary, after wiring (not shown in the drawing).

The formation of the electrodes, wiring, and the like, may be achieved, for example, by a method involving carrying out film formation through CVD or sputtering, and then carrying out patterning through lithography.

As described above, the photoelectric conversion device 1 (solar battery 2) includes the single particle film (photoelectric conversion semiconductor layer) 10, in which at least parts of the separate photoelectric conversion semiconductor particles 11, which have a mean particle diameter of not less than 1 μm and not more than 60 μm and a variation coefficient of particle diameter of less than 30%, are embedded. With this structure where the semiconductor particles 11 have a small variation coefficient of particle diameter, the single-particle film photoelectric conversion device 1 with low variation of the interelectrode distance can be achieved.

Therefore, the photoelectric conversion device 1 can be produced without requiring a high temperature process over 250° C. and thus at lower costs than those produced using a vacuum film formation process, and the photoelectric conversion semiconductor device 1 having good output stability, good photoelectric conversion efficiency and high durability can be achieved.

### (Modification)

The invention is not limited to the above-described embodiments and may be modified as appropriate without departing from the spirit and scope of the invention.

### EXAMPLES

Examples according to the invention and comparative examples are described.

### Example 1

CuInGa (5/3/2) alloy and Se powder were mixed at a molar ratio of 1:2, and CuSe was further mixed as a flux in an amount of 40 vol. % of the entire mixture. The mixture was encapsulated in a vacuum quartz ampoule, and heated at 530° C. for 20 hours with the ampoule being moved freely and rotated. After the firing, the mixture was washed with an aqueous 10% KCN solution to remove CuSe and was dried, and then was sieved using 55 μm and 40 μm meshes to provide CIGS particles having a mean particle diameter of 48 μm (the range of particle sizes was from 40 to 55 μm) and a variation coefficient of 28%. The mean particle diameter and the variation coefficient were measured using a laser diffraction/scattering particle size distribution measurement apparatus LA-920 available from HORIBA, Ltd.

A pair of metal plates (80 μm-thick aluminum foils) were prepared and regular depressions were formed in one of the metal plates to receive the CIGS particles placed thereon to form a single particle layer. The other of the metal plates held an elastic Gel-Pak sheet (GEL-FILM (trademark) WF-40/1.5-X4 available from Gel-Pak Inc.) and a polypropylene film (TRANSPROP (trademark) 0 L polypropylene film available from Translilwrap Company, Inc.), in this order. Then, the polypropylene film was positioned to cover the CIGS powder, and a pressure of 180 g/cm² was applied from the rear side of the metal plate. In this state, heating at a temperature of 200° C. was carried out for 5 minutes, and cooling was achieved in ambient air.

Then, the same operation was carried out on the opposite side of the CIGS powder, and the metal plates and the Gel-Pak sheets were peeled off to provide a photoelectric conversion semiconductor layer with the head portions and the bottom portions of the CIGS particles being exposed. Then, a 0.8 μm-thick Mo metal film was formed through sputtering on one side of the thus obtained photoelectric conversion semiconductor layer, and a 50 nm-thick CdS layer serving as a buffer layer, a 80 nm-thick i-ZnO layer, and a 500 nm-thick ZnO:Al layer were sequentially formed through sputtering on the opposite surface to provide a photoelectric conversion device.

### Example 2

A photoelectric conversion device was produced in the same manner as in Example 1, except that the metal electrode was a W electrode.

### Examples 3 to 6 and Comparative Examples 1 to 9

Photoelectric conversion devices including photoelectric conversion semiconductor particles having various mean particle diameters and variation coefficients were produced using sieves with different mesh sizes.

### (Evaluation)

Table 1 shows the range of particles size, the mean particle diameter, the variation coefficient, the type of metal electrode, the photoelectric conversion efficiency, and the photoelectric conversion efficiency after 1000 hours for each of Examples 1 to 6 and Comparative Examples 1 to 9. As shown in Table 1, it has been confirmed that high photoelectric conversion efficiency and high durability are achieved by controlling the mean particle diameter to be within the range from 1 to 60 μm and the variation coefficient to be less than 30%.

Further, with respect to the electrode at the surface opposite to the light absorbing surface, it was confirmed that a metal electrode, in particular, provides better electricity generation efficiency than a carbon electrode, and a Mo electrode is preferred.

TABLE 1

| | | | | | First | Photo- | |
|---|---|---|---|---|---|---|---|
| | | | | | Photo- | electric | |
| | | | | | electric | Conver- | |
| | Range | Mean | Varia- | | Con- | sion Ef- | Dete- |
| | of Par- | Parti- | tion | | version | ficiency | riora- |
| | ticle | cle | Coef- | Back | Effi- | After | tion |
| | Size | Size | ficient | Elec- | ciency | 1000 | Rate |
| | (μm) | (μm) | (%) | trode | (%) | hrs (%) | (%) |
| Compar- | 10-50 | 32 | 35 | Carbon | 5.8 | 3.9 | 67.2 |
| ative | | | | | | | |
| Example 4 | | | | | | | |
| Compar- | 10-50 | 32 | 35 | Mo | 6.2 | 4.0 | 64.5 |
| ative | | | | | | | |
| Example 3 | | | | | | | |
| Compar- | 15-47 | 33 | 31 | Mo | 6.5 | 4.5 | 69.2 |
| ative | | | | | | | |
| Example 2 | | | | | | | |
| Compar- | 40-55 | 49 | 28 | Carbon | 5.9 | 4.5 | 76.2 |
| ative | | | | | | | |
| Example 1 | | | | | | | |
| Example 2 | 40-55 | 49 | 28 | W | 7.0 | 6.3 | 90.0 |
| Example 1 | 40-55 | 49 | 28 | Mo | 7.7 | 7.5 | 97.4 |
| Example 3 | 45-53 | 47 | 20 | Mo | 9.2 | 9.1 | 98.9 |
| Example 4 | 1-15 | 8 | 28 | Mo | 8.4 | 8.0 | 95.2 |
| Example 5 | 15-38 | 28 | 27 | Mo | 9.3 | 9.2 | 98.9 |
| Example 6 | 53-59 | 56 | 23 | Mo | 9.2 | 8.9 | 96.7 |
| Compar- | 53-80 | 63 | 35 | Mo | 6.1 | 3.9 | 63.9 |
| ative | | | | | | | |
| Example 5 | | | | | | | |
| Compar- | 63-80 | 70 | 29 | Mo | 4.1 | 3.5 | 85.3 |
| ative | | | | | | | |
| Example 6 | | | | | | | |
| Compar- | 0.1-15 | 6 | 35 | Mo | 3.5 | 1.3 | 37.1 |
| ative | | | | | | | |
| Example 7 | | | | | | | |
| Compar- | 0.8-65 | 35 | 45 | Mo | 4.0 | 1.9 | 47.5 |
| ative | | | | | | | |
| Example 8 | | | | | | | |
| Compar- | 0.1-0.9 | 0.5 | 29 | Mo | 3.8 | 2.2 | 57.8 |
| ative | | | | | | | |
| Example 9 | | | | | | | |

### INDUSTRIAL APPLICABILITY

The photoelectric conversion device of the invention is preferably applicable to applications, such as solar batteries and infrared sensors.

What is claimed is:

1. A photoelectric conversion device comprising:
a photoelectric conversion semiconductor layer for generating an electric current when it absorbs light;
a first electrode formed in contact with a front surface forming a light absorbing surface of the semiconductor layer; and
a second electrode formed in contact with a rear surface of the semiconductor layer,
wherein the semiconductor layer comprises a single particle film comprising a binder layer and separate photoelectric conversion semiconductor particles, at least parts of the photoelectric conversion semiconductor particles being embedded in the binder layer, the photoelectric conversion semiconductor particles having a mean particle diameter of not less than 1 and not more than 60 μm and a variation coefficient of particle diameter of less than 30%, and
wherein parts of the semiconductor particles are in contact with the second electrode at the rear surface and parts of the semiconductor particles are in contact with the first electrode at the front surface via a buffer layer.

2. The photoelectric conversion device as claimed in claim 1, wherein the second electrode is a metal electrode.

3. The photoelectric conversion device as claimed in claim 1, wherein a main component of the separate photoelectric conversion semiconductor particles is at least one compound semiconductor having a chalcopyrite structure.

4. The photoelectric conversion device as claimed in claim 3, wherein the main component of the separate photoelectric conversion semiconductor particles is at least one compound semiconductor comprises a group Ib element, a group IIIb element and a group VIb element.

5. The photoelectric conversion device as claimed in claim 4, wherein the main component of the separate photoelectric conversion semiconductor particles is at least one compound semiconductor comprising
at least one group Ib element selected from the group consisting of Cu and Ag,
at least one group IIIb element selected from the group consisting of Al, Ga and In, and
at least one group VIb element selected from the group consisting of S, Se and Te.

6. A solar battery comprising the photoelectric conversion device as claimed in claim 1.
